(19) United States
(12) Patent Application Publication
(10) Pub. No.: US 2017/0372761 A1
(43) Pub. Date: Dec. 28, 2017

(54) Systems for Source Line Sensing of Magnetoelectric Junctions

(71) Applicant: Inston Inc., Santa Monica, CA (US)

(72) Inventor: Hochul Lee, Los Angeles, CA (US)

(73) Assignee: Inston Inc.

(21) Appl. No.: 15/636,555

(22) Filed: Jun. 28, 2017

Related U.S. Application Data
(60) Provisional application No. 62/355,705, filed on Jun. 28, 2016.

(51) Int. Cl. G11C 11/16; H01L 27/22; H01L 43/10

(52) U.S. Cl. CPC G11C 11/161; H01L 43/10; G11C 11/1673; G11C 11/1675; H01L 27/228

(57) ABSTRACT

Systems for performing source line sensing of magnetoelectric junctions in accordance with embodiments of the invention are disclosed. In one embodiment, a MeRAM circuit includes a plurality of voltage controlled magnetic tunnel junction bits, application of a voltage with opposite polarity increases the perpendicular magnetic anisotropy and magnetic coercivity of the free layer through the VCMA effect, each magnetoelectric junction is connected to the drain of an MOS transistor, the combination includes a MeRAM cell, each MeRAM cell includes three terminals, each connected respectively to a bit line, a source line, and at least one word line, in an array, a pulse generator and a write MOS transistor connected to the bit line and the source line, a sense amplifier and a sense MOS transistor connected to the source line and the bit line, and a current source circuit connected to the source line and the reference line.

### CROSS-REFERENCE TO RELATED APPLICATIONS

The current application claims priority to U.S. Provisional Application No. 62/355,705, filed Jun. 28, 2016, the disclosure of which is incorporated herein by reference.

### FIELD OF THE INVENTION

The present invention generally relates to electronic circuits and more specifically to the implementation of magnetoelectric junctions.

### BACKGROUND OF THE INVENTION

Devices that rely on electricity and magnetism underlie much of modern electronics. Particularly, researchers have begun to develop and implement devices that take advantage of both electricity and magnetism in spin-electronic (or so-called “spintronic”) devices. These devices utilize quantum-mechanical magnetoresistance effects, such as giant magnetoresistance (GMR) and tunnel magnetoresistance (TMR). GMR and TMR principles regard how the resistance of a thin film structure that includes alternating layers of ferromagnetic and non-magnetic layers depends upon whether the magnetizations of ferromagnetic layers are in a parallel or antiparallel alignment. For example, magnetoresistive random-access memory (MRAM) is a technology that is being developed that typically utilizes TMR phenomena in providing for alternative random-access memory (RAM) devices. In a typical MRAM bit, data is stored in a magnetic structure that includes two ferromagnetic layers separated by an insulating layer—this structure is conventionally referred to as a magnetic tunnel junction (MTJ). The magnetization of one of the ferromagnetic layers (the fixed layer) is permanently set to a particular direction, while the other ferromagnetic layer (the free layer) can have its magnetization direction free to change. Generally, the MRAM bit can be written by manipulating the magnetization of the free layer such that it is either parallel or antiparallel with the magnetization of the fixed layer; and the bit can be read by measuring its resistance (since the resistance of the bit will depend on whether the magnetizations are in a parallel or antiparallel alignment).

### SUMMARY OF THE INVENTION

Systems for performing source line sensing of magnetoelectric junctions in accordance with embodiments of the invention are disclosed. In one embodiment, a magnetoelectric random access memory circuit includes a plurality of voltage controlled magnetic tunnel junction bits each magnetoelectric junction includes at least one free magnetic layer, one fixed magnetic layer, and one dielectric interposed between the two magnetic layers, application of a voltage with a given polarity to the magnetoelectric junction reduces the perpendicular magnetic anisotropy and the magnetic coercivity of the free layer through the voltage controlled magnetic anisotropy (VCMA) effect, application of a voltage with opposite polarity increases the perpendicular magnetic anisotropy and magnetic coercivity of the free layer through the VCMA effect, each magnetoelectric junction is connected to the drain of an MOS transistor, the combination includes a MeRAM cell, each MeRAM cell includes three terminals, each connected respectively to a bit line, a source line, and at least one word line, in an array, a pulse generator and a write MOS transistor connected to the bit line and the source line, a sense amplifier and a sense MOS transistor connected to the source line and the bit line, and a current source circuit connected to the source line and the reference line.

In a further embodiment, the magnetoelectric junction bit free layer includes a combination of Co, Fe and B.

In another embodiment, the magnetoelectric junction bit dielectric barrier includes MgO.

In a still further embodiment, the magnetoelectric junction bit free layer is placed adjacent to a metal layer, includes one or a combination of the elements Ta, Ru, Mn, Pt, Mo, Ir, Hf, W, and Bi.

In a still another embodiment, the free layer magnetization changes direction in response to a voltage pulse across the magnetoelectric junction bit, which is timed to approximately half the ferromagnetic resonance period of the free layer.

In a yet further embodiment, the free layer magnetization has two stable states which are perpendicular to plane in the absence of voltage.

In yet another embodiment, the free layer magnetization has two stable states in plane in the absence of voltage.

In a further embodiment again, the magnetoelectric junction bit has a circular shape.

In another embodiment again, the magnetoelectric junction bit has an elliptical shape.

In a further additional embodiment, the pulse generator involves a bit line driver.

In another additional embodiment, where the source of a MOS transistor of each MeRAM cell is connected to the source line.

In a still yet further embodiment, at least one output of the current source circuit is connected to the source line and supplies a constant current during the read operation.

In still yet another embodiment, a second output of the current source circuit is connected to the reference line and supplies a constant current during the read operation.

In a still further embodiment again, at least one input of the sense amplifier is connected to the source line.

In still another embodiment again, a second input of the sense amplifier is connected to the reference line.

In a still further additional embodiment, the drain of a MOS transistor is connected to the reference line.

In still another additional embodiment, the source of a MOS transistor is connected to a reference resistor.

In a yet further embodiment again, the drain of the sense MOS transistor is connected to the bit line.

In a yet further embodiment again, the drain of the write MOS transistor is connected to the source line.

Other objects, advantages and novel features, and further scope of applicability of the present invention will be set forth in part in the detailed description to follow, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The description will be more fully understood with reference to the following figures, which are presented as exemplary embodiments of the invention and should not be construed as a complete recitation of the scope of the invention, wherein:

FIG. 1 conceptually illustrates a source line sensing MeRAM system in accordance with certain embodiments of the invention.

FIG. 2 conceptually illustrates source line sensing MeRAM control signals in read mode in accordance with certain embodiments of the invention.

FIG. 3 conceptually illustrates a source line sensing MeRAM cell in accordance with certain embodiments of the invention.

FIG. 4 conceptually illustrates the implementation of a plurality of MEJs in accordance with certain embodiments of the invention.

FIG. 5 conceptually illustrates a MEJ that includes in-plane magnetization in accordance with certain embodiments of the invention.

FIG. 6 conceptually illustrates a MEJ that includes out of plane magnetization in accordance with certain embodiments of the invention.

FIG. 7A conceptually illustrates a MEJ that includes adjunct layers to facilitate its operation in accordance with embodiments of the invention.

FIG. 7B conceptually illustrates a MEJ that includes adjunct layers that generate stray magnetic fields to facilitate its operation in accordance with embodiments of the invention.

FIGS. 8A and 8B conceptually illustrate the operation of a MEJ in accordance with certain embodiments of the invention.

FIGS. 9A and 9B conceptually illustrate MEJs that include a semi-fixed layer in accordance with certain embodiments of the invention.

FIG. 10 conceptually illustrates a MEJ having a metal line parallel to and proximate the free layer where current can pass through the metal line and thereby induce spin-orbit torques that can cause the ferromagnetic free layer to adopt a particular magnetization direction in accordance with certain embodiments of the invention.

### DETAILED DESCRIPTION

Turning now to the drawings, systems, and methods for source line sensing of magnetoelectric junctions are illustrated. In the field of random access memory, bits of data in the memory are read or “sensed” to determine the value of each bit of stored data. The current application describes a scheme for sensing memory bits on the source line instead of the bit line as in traditional applications. The source line sensing system can reduce read disturbance and increase the sensing margin over traditional applications. These improvements allow for the use of magnetoelectric random access memories (MeRAM) in an increased number of applications.

Some challenges currently prevent MeRAM from being implemented in certain applications including embedded system memory applications. One potential problem is read failure, which occurs when a sensing circuit cannot distinguish between two states of the memory cell without changing the memory state due to the small sensing margin. The sensing margin can be defined as the difference between the voltage from the sense line node and the reference node. This can be caused by the low tunneling magnetoresistance (TMR) ratio in material systems typically used in spin-transfer torque magnetic random-access memory (STT-RAM) and MeRAM. As the sensing margin decreases, the memory can become more susceptible to noise, potentially increasing the read failure and perhaps requiring a more sophisticated circuit to amplify signals.

Another possible issue in traditional MeRAM applications is read disturbance, which is understood as a chance flipping of the magnetoelectric junction (MEJ) state after applying an electric read pulse (i.e., the probability of a destructive read), which is not affected by TMR but in many cases by thermal stability. A read disturbance can happen during reading when the bit lines of an MeRAM as well as STT-RAM are charged to a certain voltage level (sensing voltage).

Conventional sensing schemes such as bit line sensing (BLS) in MeRAM applications apply a positive voltage across a device to sense the state of the device, which might cause a read disturbance. The reading of a MEJ, unlike typical STT devices, is strongly affected by the choice of voltage polarity during the read operation, since the voltage-controlled magnetic anisotropy (VCMA) effect results in a change of coercivity in the free layer under voltage application. The change in coercivity can vary the thermal stability of the free layer. In many instances this can be related to the VCMA effect modulating the coercivity under the electric bias condition, which in turn can change the thermal stability of the device. Source line sensing (SLS) applies a sensing voltage in an opposite polarity compared to that of the BLS for reducing read disturbance by enhancing coercivity.

Source line sensing on a typical MeRAM chip is applied over a plurality of cell grids or groupings of cells. These cells are typically made up of memory cells. Numerous applications have used magnetic tunnel junctions (MTJs) as memory cells in magnetoresistive random access memory (MRAM). However, the magnetoelectric tunnel junction (MEJ) is an emerging variant of the MTJ device used in MRAM, which exploits magnetoelectric interface effects to control its free layer magnetization, and tunneling magnetoresistance (TMR) to read its state. Generally, the coercivity of the free layer of a MEJ can be reduced using voltage-controlled magnetic anisotropy (VCMA) phenomena, thereby making the free layer more easily switched to the opposite direction (‘writeable’). It has been demonstrated that such devices employing VCMA principles result in marked performance improvements over conventional MTJs. The electric-field-controlled nano-magnets used in MEJs are being developed as basic building blocks for the next generation of memory and logic applications, since they have the potential for significant reductions in power dissipation, offer high endurance and density, and can be applied to high-speed operation systems.

The MEJ differs from a conventional magnetic tunnel junction in that an electric field is used to induce switching, in lieu of substantial current flow for utilizing spin transfer torque (STT) in a current-controlled MTJ. Compared to MTJs, MEJs have at least three noticeable advantages: i) extremely low dynamic switching energy due to significant reduction of Ohmic loss, ii) sub-nanosecond writing speed based on precessional switching (which for STT devices requires very large currents through the device to achieve the same speed), iii) high density in a memory array application due to the use of minimum sized access transistors or diodes in a cell.

However, as a result of coercivity dependence, using a traditional BLS scheme has a possibility of causing read disturbances in MeRAM cell arrays. This may be especially the case for embedded system memory applications, which may only require a relatively short retention time (<1 ms) since they have a relatively low thermal stability (Δ˜20-30) compared to storage applications (typically Δ>40). In certain embodiments, the BLS scheme sensing voltage (pre-charge voltage) on the bit line should be limited, which, however, can reduce the sensing margin. Utilizing a source line sensing system in accordance with embodiments of the invention can reduce read disturbances and allow for the use of MeRAM in an increased amount of applications such as embedded system memory applications.

Source-line sensing systems can utilize a number of MEJ variants depending on the specific application required. In broad terms, a fundamental MEJ structure includes a ferromagnetic (FM) fixed layer, a FM free layer that has a uniaxial anisotropy, and a dielectric layer separating the FM fixed layer and FM free layer. For simplicity, it should be noted that the terms “FM fixed layer” and “fixed layer” will be considered equivalent throughout this application, unless otherwise stated; similarly, the terms “FM free layer”, “ferromagnetic free layer,” “free layer that has a uniaxial anisotropy”, and “free layer” will also be considered equivalent throughout this application, unless otherwise stated.

Generally, the FM fixed layer in accordance with many embodiments of the invention may have a fixed magnetization direction, i.e. the direction of magnetization of the FM fixed layer does not typically change during the normal operation of the MEJ. Conversely, in certain embodiments, the FM free layer can adopt a magnetization direction that is either substantially parallel with or antiparallel with the FM fixed layer, i.e. during the normal operation of the MEJ, the direction of magnetization can be made to change. For example, the FM free layer may have a magnetic uniaxial anisotropy, whereby it has an “easy axis” that is substantially aligned with the direction of magnetization of the FM fixed layer. The “easy axis” refers to the axis, along which the magnetization direction of the layer prefers to align. In other words, an easy axis is an energetically favorable direction (axis) of spontaneous magnetization that is determined by various sources of magnetic anisotropy including, but not limited to, magnetocrystalline anisotropy, magnetoelastic anisotropy, geometric shape of the layer, etc. Relatedly, an “easy plane” is a plane whereby the direction of magnetization is favored to be within the plane, although there is no bias toward a particular axis within the plane.

Typically, VCMA phenomena can be relied on in switching the FM free layer's characteristic magnetization direction, i.e. the MEJ can be configured such that the application of a potential difference across the MEJ can reduce the coercivity of the free layer, which can allow the free layer's magnetization direction to be switched more easily. In other words, with a reduced coercivity, the FM free layer can be subject to magnetization that can make it substantially parallel with or substantially antiparallel with the direction of the magnetization for the FM fixed layer.

Source line sensing systems in accordance with embodiments of the invention use the VCMA effect to improve read disturbance by re-engineering the structure of the MeRAM and the control signals. Unlike traditional bit line sensing schemes, a sense amplifier and a current source are connected to the source line instead of the bit line. A plurality of MeRAM cells are attached to both the source line and the bit line. In certain embodiments, a pulse generator is connected to the bit line of the system. Selection of a MEJ within a MeRAM cell is accomplished by applying a voltage to the MeRAM word line during each operation mode. The source line sensing MeRAM system will utilize the sense amplifier to sense the potential difference in voltages from the sense line and the reference line to generate an amplified output representing either a parallel or antiparallel state of the MEJ in the MeRAM cell. Certain embodiments may utilize the pulse generator to provide a write pulse to the bit line to improve the sensing.

While MEJs demonstrate much promise in use as memory cells in source line sensing systems, their potential applications and variations continue to be explored. For example, U.S. Pat. No. 8,841,739 (the '739 patent) to Khalili Amiri et al. discloses DIOMEJ cells that utilize diodes (e.g. as opposed to transistors) as access devices to MEJs. As discussed in the '739 patent, using diodes as access devices for MEJs can confer a number of advantages and thereby make the implementation of MEJs much more practicable. The disclosure of the '739 patent is hereby incorporated by reference in its entirety, especially as it pertains to implementing diodes as access devices for MEJs. Furthermore, U.S. patent application Ser. No. 14/073,671 (“the '671 patent application”) to Khalili Amiri et al. discloses MEJ configurations that demonstrate improved writeability and readability, and further make the implementation of MEJs more practicable. The disclosure of the '671 patent application is hereby incorporated by reference in its entirety, especially as it pertains to MEJ configurations that demonstrate improved writeability and readability. A conceptual illustration of a source line sensing system is discussed in the following section.

### Source Line Sensing MeRAM Systems

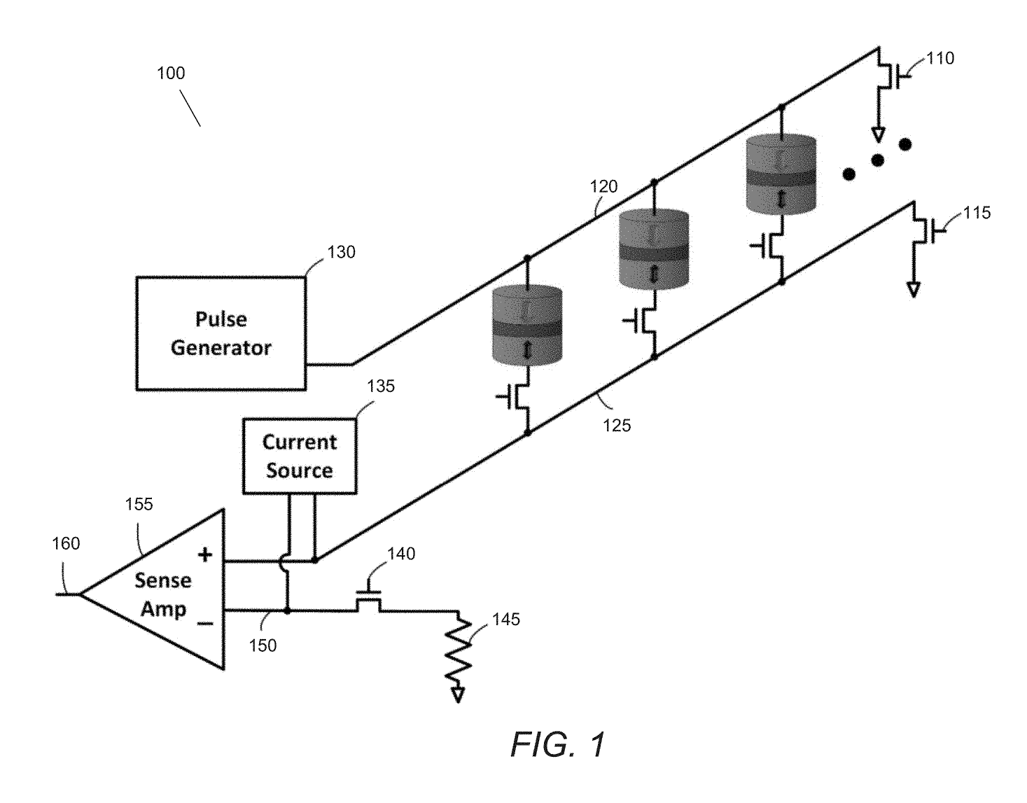

Turning now to FIG. 1, a conceptual illustration of a source line sensing MeRAM system in accordance with embodiments of the invention is shown. In general, the source line sensing system comprises a series of MeRAM memory cells connected in parallel on both a bit line and a source line. The source line sensing is accomplished by sending a current into the source line of the MeRAM memory units and then utilizing the sense amplifier to generate an output signal by sensing and amplifying the potential difference in voltage between the sense line and the reference line. Indeed, applying the sensing voltage on the source line is a key component of the source line sensing MeRAM system as applying the voltage may increase the coercivity of the MEJs during the read operation, taking advantage of the odd dependence of coercivity on voltage in typical MEJ systems. In many embodiments, a pulse generator is used to send a signal to the MeRAM memory cells on the bit line. It should be noted that applying a voltage to the bit line may have the same effect as an SLS scheme would, generating a negative bias requires more resources such as, but not limited to, a charge pump circuit, in the chip where it has a positive power supply and common ground.

A source line sensing system uses the VCMA effect to reversely improve read disturbance by engineering the structure of the MeRAM and the control signals. In several embodiments, selection of a MEJ within a MeRAM cell can be accomplished by applying a voltage to the MeRAM word line during each operation mode. In certain embodiments, the sense amplifier senses the potential difference in voltages from the sense line and the reference line to generate an output representing either a parallel or antiparallel state of the MEJ in the MeRAM cell.

In additional embodiments, the source line sensing system may also contain a pair of MOS transistors connected to the bit line and sense lines respectively. The bit line MOS transistor is typically labelled a Sense_G signal, while the MOS transistor attached to the sense line is labelled a Write_G signal. Additionally, a reference word line (RWL) transistor is typically attached to the sense amplifier and current source generator that allows for current to flow through a reference transistor (REF).

A source line sensing MeRAM system in accordance with several embodiments of the invention is disclosed in FIG. 1. In many embodiments, a source line sensing MeRAM system 100 may include pulse generator 130 connected to a bit line 120 which itself is connected to a MOS transistor (Sense_G) 110. In additional embodiments, source line 125 may be connected to another MOS transistor (Write_G) 115 and to a series of MeRAM cells between the bit line 120. Additionally, in certain embodiments, the source line 125 is connected to a current source 135 and a sense amplifier 155. In additional embodiments, the sense amplifier 155 and current source 135 are also connected to a reference signal 150 which itself can be connected to both a reference word line 140 and a reference resistor 145. Finally, in an additional number of embodiments, the output 160 of the sense amplifier 155 can determine the output of the MeRAM system.

Although specific conceptual embodiments are described above regarding source line sensing MeRAM systems with respect to FIG. 1, any of a number of methods to implement a source line sensing MeRAM system in a system can be utilized as appropriate to the requirements of specific applications in accordance with various embodiments of the invention. A discussion about the control signals of a source line sensing system is covered in the following section.

### Source Line Sensing MeRAM Control Signals

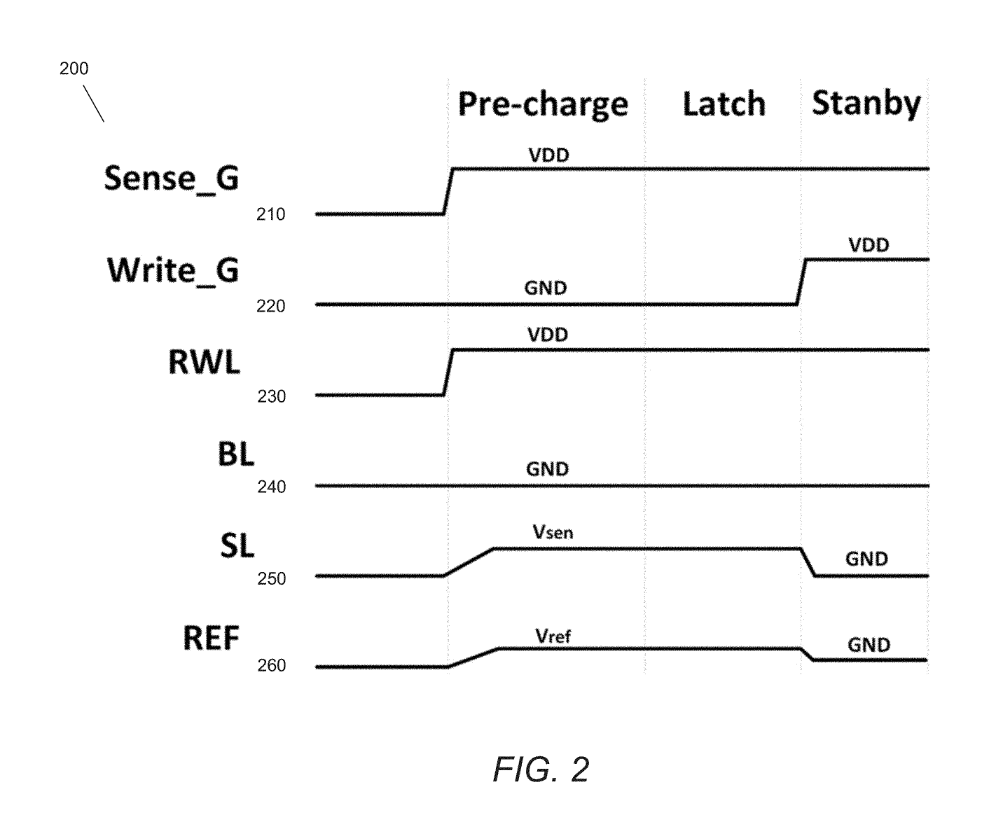

A graph depicting control signals for a source line sensing MeRAM system in the read mode is conceptually illustrated in FIG. 2. The control signal graph 200 may contain a Sense_G signal 210 that represents a MOS transistor connected to the bit line in accordance with many embodiments of the invention. Similarly, a Write_G signal 220 represents a MOS transistor connected to the source line. Further signals on the control signal graph 200 include the reference word line (RWL) voltage signal 230, a signal representing the bit line (BL) voltage 240, a similar signal representing the source line (SL) voltage 250, and the reference line (REF) voltage signal 260I

Generally, a source line sensing MeRAM system has two main modes: write and read. In many embodiments, to enable a write mode, the BL 240 may be disconnected to the ground by applying a ground to the Sense_G 210 while the potential of the source line discharges to the ground level by applying a voltage on the Write_G 220. Then, the pulse generator provides a write pulse to the BL 240.

Conversely, in numerous embodiments, a read mode in source line sensing MeRAM systems can be accomplished by having the bit line BL 240 grounded by applying a voltage on the Sense_G transistor 210 and then disconnecting the source line SL 250 to the ground by applying a ground to Write_G 220. Additionally, in certain embodiments, a voltage is also applied on the RWL 230 which may allow current to flow through the reference transistor REF 260. The current source of the MeRAM system supplies a current to the source line SL 250 and reference transistor REF 260, generating Vsen and Vref respectively. This potential difference is sensed by the sense amplifier which then generates a digital output. In a number of embodiments, the sense amplifier output can be a 0 for antiparallel states detected and 1 for parallel states detected.

Although specific conceptual embodiments are described above regarding control signals in source line sensing systems with respect to FIG. 2, any of a number of methods to implement control signals in a source line sensing system can be utilized as appropriate to the requirements of specific applications in accordance with various embodiments of the invention. A discussion about the constituent parts of a MeRAM cell is covered in the following section.

### Source Line Sensing MeRAM Cells

Source line sensing MeRAM systems in accordance with embodiments of the invention utilize a series of MeRAM cells to store bits of data. The MeRAM cells contain a combination of MEJ cell and access transistor. The MEJ cells are discussed in more detail in the following sections and can be composed of many different embodiments. In many embodiments, the fixed layer side of the MEJ is connected to the bit line while the free layer is connected to the access transistor, which itself contains a word line transistor and connection to the source line.

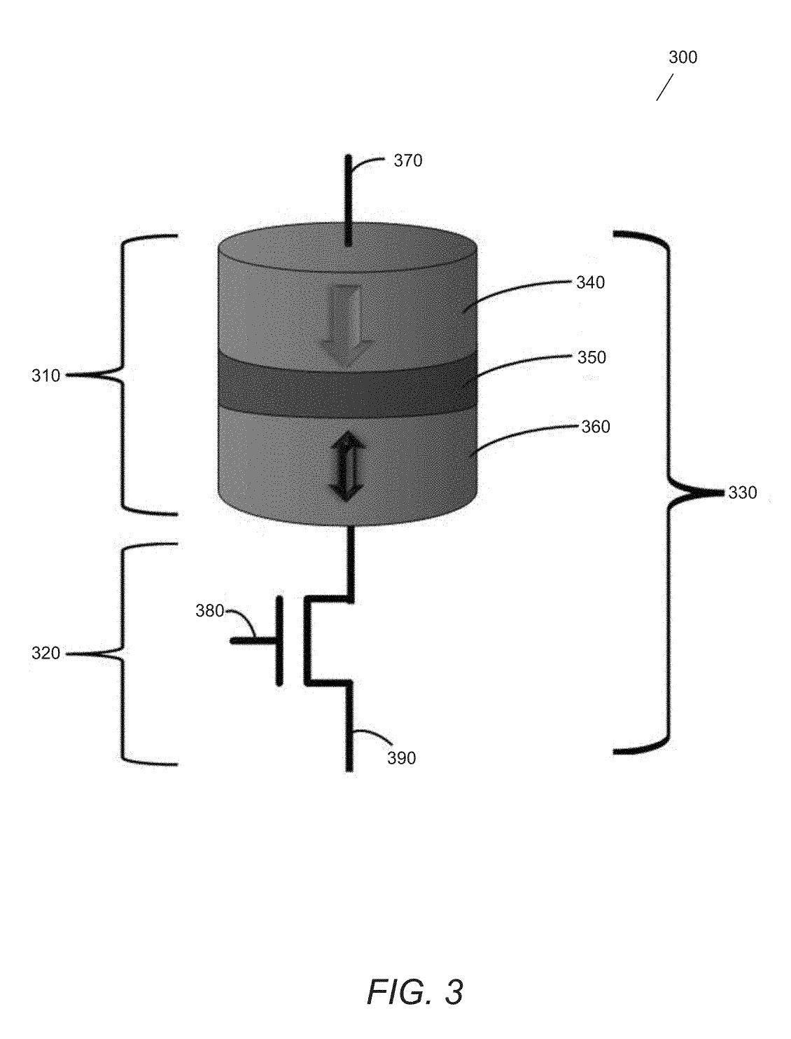

A conceptual illustration of a MeRAM cell in accordance with embodiments of the invention is shown in FIG. 3. In several embodiments, the MeRAM cell 300 primarily consists of a MeRAM storage element 330. In a number of embodiments, the storage element 330 can be understood as being composed of a MEJ portion 310 and an access transistor 320. In certain embodiments, the MEJ 310 includes a fixed layer 340 and a magnetic free layer 360 with a tunnel barrier 350 in between. In further embodiments, the access transistor 320 may include a word line 380 and a source line 390. Additionally, still further embodiments may have a bit line 370 accessing the MEJ portion 310.

Although specific conceptual embodiments are described above regarding source line sensing MeRAM cells with respect to FIG. 3, any of a number of source line sensing MeRAM cells in a system can be utilized as appropriate to the requirements of specific applications in accordance with various embodiments of the invention. A discussion about the constituent parts of a source line sensing MeRAM system is covered in the following section.

### Implementing a Plurality of MEJs

Pluralities of MEJs can be implemented in any of a variety of configurations for use in MeRAM cells in accordance with embodiments of the invention. Source line sensing MeRAM systems typically utilize MEJs as the MeRAM memory storage element. These MEJs are often implemented as a plurality of MEJs in a contained system. In certain embodiments, the MEJs in contained systems may be implemented as a series of MeRAM cells in a MeRAM system. For example, the '671 patent application (incorporated by reference above) discloses MEJ configurations that include a second dielectric layer proximate the free layer and configured to enhance the VCMA effect. It should be clear that any suitable MEJ configuration may be incorporated in accordance with embodiments of the invention.

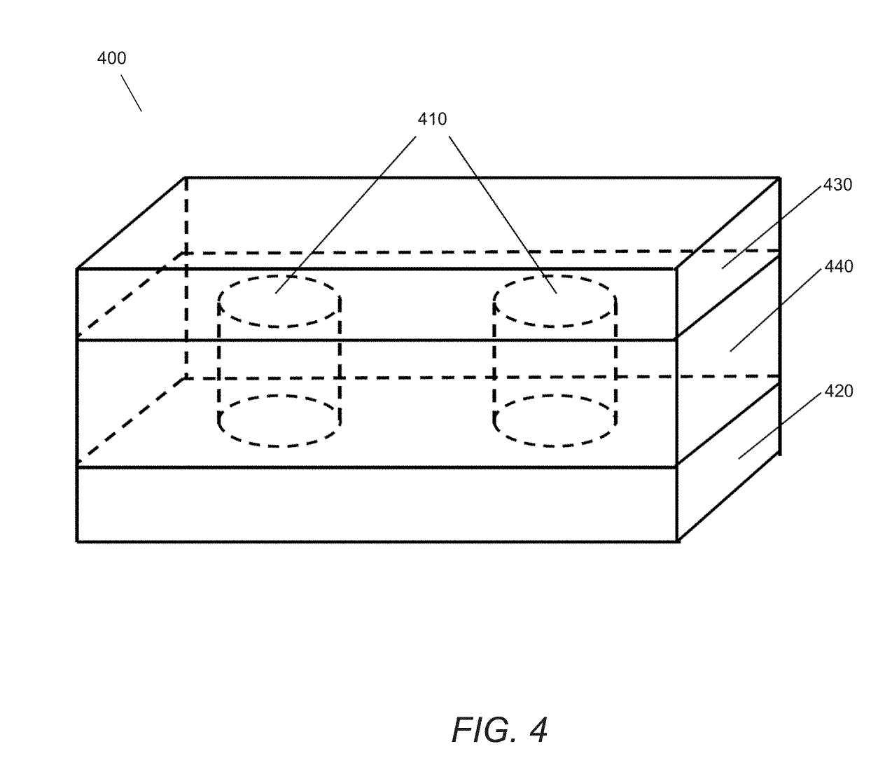

Note that while the subsequent discussions largely regard the operation of single MEJs, it should of course be understood that in many embodiments, a plurality of MEJs are implemented together. For example, the '671 patent application discloses MeRAM configurations that include a plurality of MEJs disposed in a cross-bar architecture. It should be clear that MEJ systems can include a plurality of MEJs in accordance with embodiments of the invention. In several embodiments where multiple MEJs are implemented, they can be separated by field insulation, and encapsulated by top and bottom layers. Thus, for example, FIG. 4 conceptually illustrates the implementation of two MEJs that are housed within encapsulating layers and separated by field insulation. In particular, the MEJs 410 are encapsulated within a bottom layer 420 and a top layer 430. In several embodiments, field insulation 440 is implemented to isolate the MEJs and facilitate their respective operation. It should of course be appreciated that each of the top and bottom layers can include one or multiple layers of materials/structures. As can also be appreciated, the field insulation material can be any suitable material that functions to facilitate the operation of the MEJs in accordance with embodiments of the invention.

Although specific conceptual embodiments are described above regarding implementing a plurality of MEJs with respect to FIG. 4, any of a number of methods to implement a plurality of MEJs in a system can be utilized as appropriate to the requirements of specific applications in accordance with various embodiments of the invention. A discussion about the fundamental structure of magnetoelectric junctions is covered in the following section.

### Fundamental Magnetoelectric Junction Structures

Magnetoelectric junctions used in source line sensing MeRAM systems can be described conceptually as having a unique structure. As previously discussed, a typical MEJ contains a fixed layer with a magnetic direction that does not change, a free layer that has a magnetic direction that may change, and an insulating layer between the fixed and free layers.

The free layer may have a magnetic uniaxial anisotropy, whereby it has an “easy axis” that is substantially aligned with the direction of magnetization of the fixed layer. The “easy axis” refers to the axis, along which the magnetization direction of the layer prefers to align. In other words, an easy axis is an energetically favorable direction (axis) of spontaneous magnetization. In several embodiments, the free layer having its magnetic direction is parallel to the easy axis, the direction of the magnetization of the fixed layer can be considered to be ‘substantially aligned’, resulting in an information state that can have a single definition. Likewise, when the free layer has a magnetic direction that is antiparallel with the “easy axis”, a second information state can be derived. In a number of embodiments, these two information states can be determined by the difference in resistance of the MEJ in each state.

In many embodiments, the magnetization direction, and the related characteristics of magnetic anisotropy, can be established for the FM fixed and FM free layers using any suitable method. For instance, the shapes of the constituent FM fixed layer, FM free layer, and dielectric layer, can be selected based on desired magnetization direction orientations. For example, in certain embodiments, implementing FM fixed, FM free, and dielectric layers that have an elongated shape, e.g. have an elliptical cross-section, may tend to induce magnetic anisotropy that is in the direction of the length of the elongated axis—i.e. the FM fixed and FM free layers will possess a tendency to adopt a direction of magnetization along the length of the elongated axis. In other words, the direction of the magnetization is ‘in-plane’. Alternatively, in several embodiments of the invention, where it is desired that the magnetic anisotropy has a directional component that is perpendicular to the FM fixed and FM free layers (i.e., ‘out-of-plane’), the shape of the layers can be made to be symmetrical, e.g. circular, along with the FM layers being made thinner. In this case, while the tendency of the magnetization to remain in-plane may still exist, it may not have a preferred directionality within the plane of the layer. In other several embodiments, because the FM layers are relatively thinner, the anisotropic effects that result from interfaces between the FM layers and any adjacent layers, which tend to be out-of-plane, may tend to dominate the overall anisotropy of the FM layer. Alternatively, a material may be used for the FM fixed or free layers which have a bulk perpendicular anisotropy, i.e. an anisotropy originating from its bulk (volume) rather than from its interfaces with other adjacent layers. In yet many additional embodiments, the FM free or fixed layers may also consist of a number of sub-layers, with the interfacial anisotropy between individual sub-layers giving rise to an effective bulk anisotropy to the material as a whole. Additionally, in numerous embodiments, FM free or fixed layers may be constructed which combine these effects, and for example have both interfacial and bulk contributions to perpendicular anisotropy.

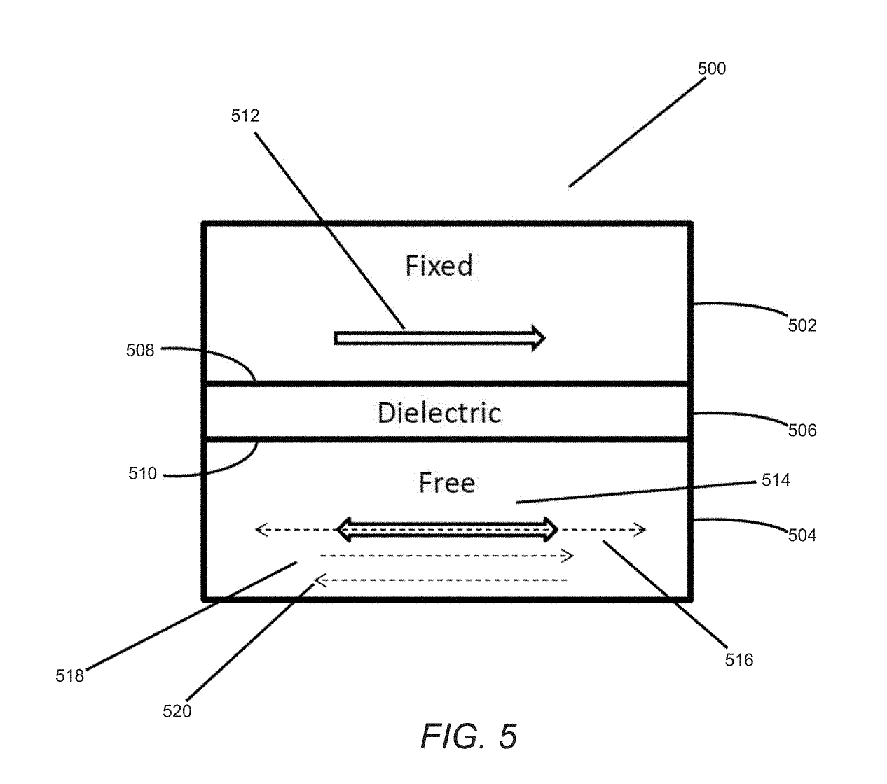

FIG. 5 conceptually illustrates a MEJ whereby a FM fixed layer and a FM free layer are separated by, and directly adjoined to, a dielectric layer. In particular, in accordance with many embodiments of the invention, the MEJ 500 can include a FM fixed layer 502 that can be adjoined to a dielectric layer 506, thereby forming a first interface 508; the MEJ can further include a FM free layer 504 that may be adjoined to a dielectric layer 506 on an opposing side of the first interface 508, thereby forming a second interface 510. In many embodiments, the MEJ 500 may have a FM fixed layer 502 that has a magnetization direction 512 that is in-plane, and depicted in this particular illustration as being from left to right. Accordingly, the FM free layer can be configured such that it can adopt a magnetization direction 514 that is either parallel with or antiparallel with the magnetization direction of the FM fixed layer. For reference, the easy axis 516 is illustrated, as well as a parallel magnetization direction 518, and an antiparallel magnetization direction 520. In several embodiments, additional contacts (capping or seed materials, or multilayers of materials, not shown) may be attached to the FM free layer 504 and the FM fixed layer 502, thereby forming additional interfaces. The contacts may both contribute to the electrical and magnetic characteristics of the device by providing additional interfaces, and can also be used to apply a potential difference across the device. Additionally, it should of course be understood that MEJs can include metallic contacts that can allow them to interconnect with other electrical components.

In many embodiments, by appropriately selecting adjacent materials, the MEJ can be configured such that the application of a potential difference across the FM fixed layer and the FM free layer can modify the magnetic anisotropy of the FM free layer. For example, whereas in FIG. 5, the magnetization direction of the FM free layer is depicted as being in-plane, the application of a voltage may distort the magnetization direction of the FM free layer such that it includes a component that is at least partially out of plane. The particular dynamics of the modification of the magnetic anisotropy will be discussed below in the section entitled “General Principles of MEJ Operation.” In a number of embodiments, suitable materials for the FM layers such that this effect can be implemented include, but are not limited to, iron, nickel, manganese, cobalt, CoFeB, FeGaB, FePd, FePt, CoFe, FeB, NiB, and NiFeB. Further, any compounds or alloys that include these materials may also be suitable. In several embodiments, suitable materials for the dielectric layer include MgO and Al₂O₃. Of course, it should be understood that the material selection is not limited to those recited—any suitable FM material can be used for the FM fixed and free layers, and any suitable material can be used for the dielectric layer. It should also be understood that each of the FM free layer, FM fixed layer, and dielectric layer may consist of a number of sub-layers, which acting together provide the functionality of the respective layer.

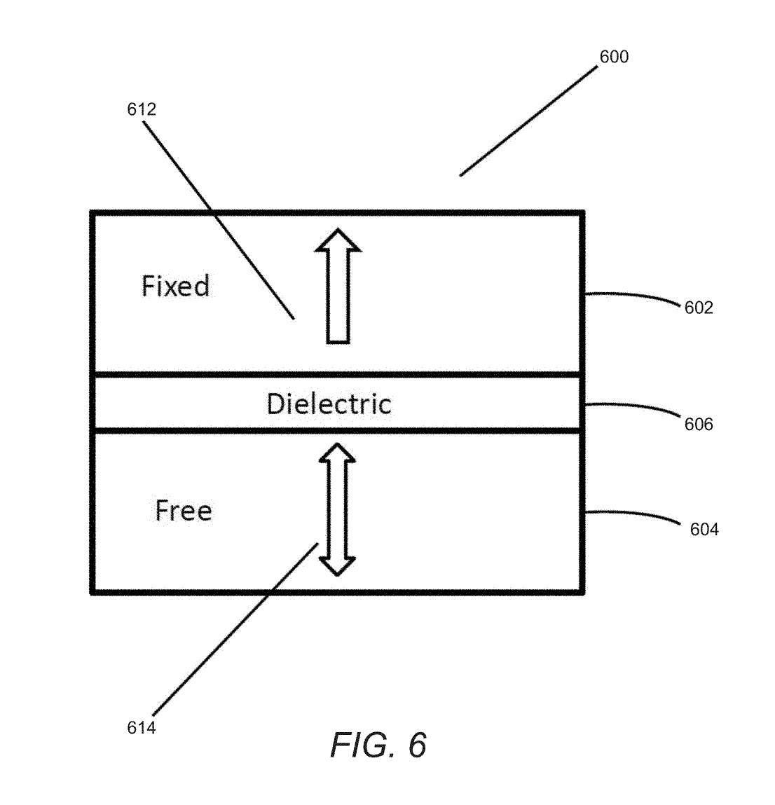

FIG. 6 conceptually illustrates a MEJ whereby the orientation of the magnetization directions can be perpendicular to the plane of the constituent layers. In particular, the MEJ 600 can be similarly configured to that seen in FIG. 5, including a FM fixed layer 602 and an FM free layer 604 adjoined to a dielectric layer 606. However, unlike the MEJ in FIG. 5, the magnetization directions of the FM fixed and FM free layers, 612 and 614 respectively, are oriented perpendicularly to the layers of the MEJ. In several embodiments, additional contacts (capping or seed materials, or multilayers of materials, not shown) may be attached to the FM free layer 604 and the FM fixed layer 602, thereby forming additional interfaces. In additional embodiments, the contacts both contribute to the electrical and magnetic characteristics of the device by providing additional interfaces, and can also be used to apply a potential difference across the device. It should also be understood that each of the FM free layer, FM fixed layer, and dielectric layer may consist of a number of sub-layers, which acting together can provide the functionality of the respective layer.

Although specific conceptual illustrations are described above for both in-plane and out-of-plane MEJ structures with reference to FIGS. 5-6, any of a variety of direction of magnetization for the FM layers can be utilized as appropriate to the requirements of specific applications in accordance with various embodiments of the invention. A discussion on the possibility of multiple layers in a MEJ in accordance with several embodiments of the invention is discussed further below.

### Adjunct Layers to Facilitate MEJ Operation

In many embodiments, a MEJ includes additional adjunct layers that function to facilitate the operation of the MEJ. For example, in certain embodiments, the FM free layer includes a capping or seed layer, which can (1) help induce greater electron spin perpendicular to the surface of the layer, thereby increasing its perpendicular magnetic anisotropy, and/or (2) can further enhance the sensitivity to the application of an electrical potential difference.

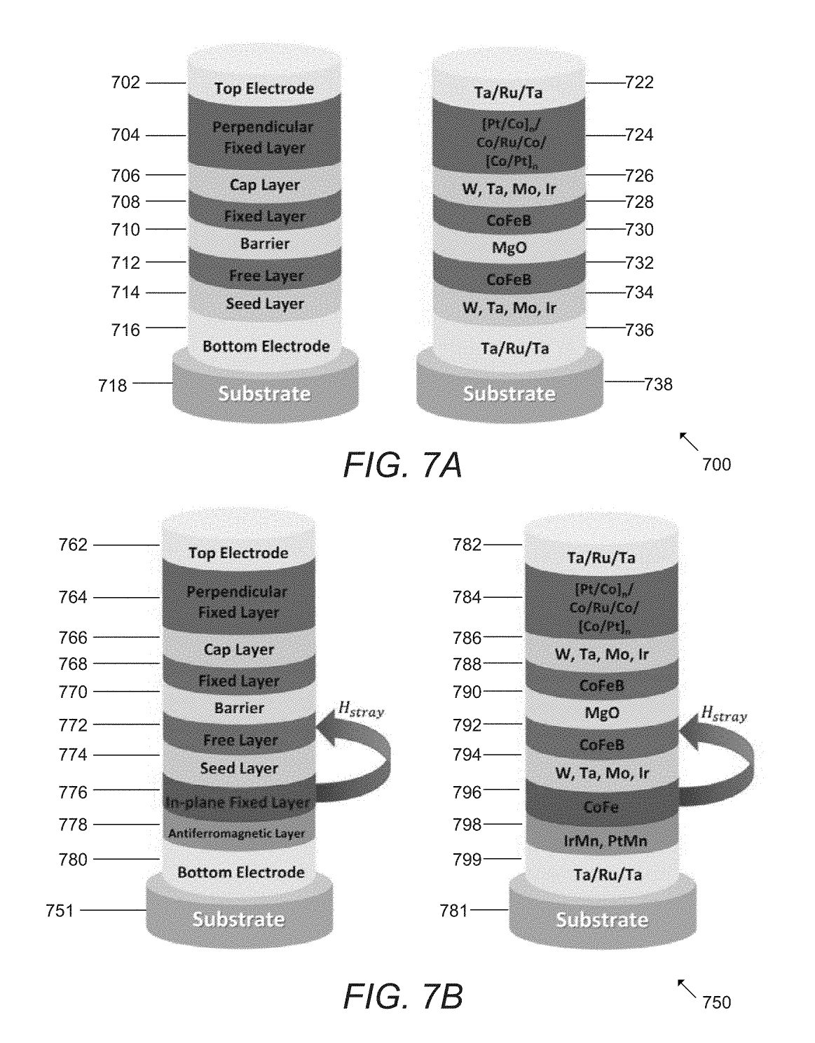

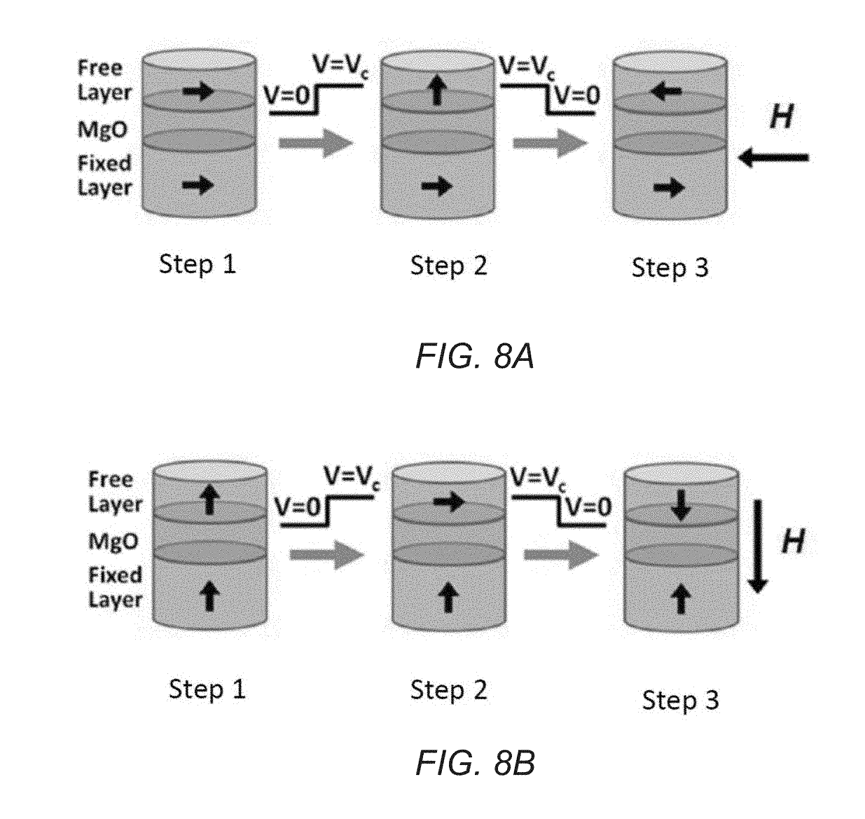

FIG. 7A conceptually illustrates MEJ structures 700 that include multiple layers that can work in aggregate to facilitate the functionality of the MEJ 700. In several embodiments, a pillar section extends from a substrate section 718, 738. In many embodiments, a voltage is applied between the top and bottom of the pillar. In certain embodiments, a pillar may comprise layers in a certain order type and materials: a top electrode 702 (e.g. Ta/Ru/Ta 722), perpendicular fixed layer 704 (e.g. Pt/Co, Co/Ru/Co, Co/Pt 724), cap layer 706 (e.g. W, Ta, Mo, Ir 726), fixed layer 708 (e.g. CoFeB 730), barrier 710 (e.g. MgO 730), free layer 712 (e.g. CoFeB 732), seed layer 714 (e.g. W, Ta, Mo, Ir 734), and bottom electrode 716 (e.g. Ta/Ru/Ta 736), although those skilled in the art will recognize that this layer order can be adjusted based on the specific requirements of the application.

FIG. 7B conceptually illustrates MEJ structures 750 wherein the in-plane fixed layer provides an in-plane stray field for achieving voltage-controlled precessional switching. In a number of embodiments, the stray field effects of the in-plane fixed layer allows the MEJ to function without the need for an externally applied magnetic field. In numerous embodiments, a pillar section extends from a substrate section 751, 781. In still numerous embodiments, a pillar may comprise layers in a certain order type and materials: a top electrode 762 (e.g. Ta/Ru/Ta 782), perpendicular fixed layer 764 (e.g. Pt/Co, Co/Ru/Co, Co/Pt 784), cap layer 766 (e.g. W, Ta, Mo, Ir 786), fixed layer 768 (e.g. CoFeB 788), barrier 770 (e.g. MgO 790), free layer 772 (e.g. CoFeB 792), seed layer 774 (e.g. W, Ta, Mo, Ir 794), in-plane fixed layer 776 (e.g. CoFe 796), antiferromagnetic layer 778 (e.g. IrMn, PtMn 798), and bottom electrode 780 (e.g. Ta/Ru/Ta 799), although those skilled in the art will recognize that this layer order can be adjusted based on the specific requirements of the application.

Although specific conceptual embodiments are described above for adjunct layers on a MEJ with reference to FIG. 7A-B, any of a number of FM layers in MEJ systems can be utilized as appropriate to the requirements of specific applications in accordance with various embodiments of the invention. For example, in numerous embodiments materials based on ruthenium, hafnium, and palladium, may be used as cap and seed layers. A discussion on the general principles of operation for a MEJ in accordance with several embodiments of the invention is discussed further below.

### General Principles of MEJ Operation

MEJ operating principles—as they are currently understood—are now discussed. Note that embodiments of the invention are not constrained to the particular realization of these phenomena. Rather, the presumed underlying physical phenomena are being presented to inform the reader as to how MEJs are believed to operate. MEJs generally function to achieve two distinct states using the principles of magnetoresistance. As mentioned above, magnetoresistance principles regard how the resistance of a thin film structure that includes alternating layers of ferromagnetic and non-magnetic layers depends upon whether the ferromagnetic layers are in a substantially parallel or antiparallel alignment. Thus, a MEJ can achieve a first state where its FM layers have magnetization directions that are substantially parallel, and a second state where its FM layers have magnetization directions that are substantially antiparallel.

MEJs further rely on voltage-controlled magnetic anisotropy (VCMA) phenomena. Generally, VCMA phenomena regard how the application of a voltage to a ferromagnetic material that is adjoined to an adjacent dielectric layer can impact the characteristics of the ferromagnetic material's magnetic anisotropy. For example, it has been demonstrated that the interface of oxides such as MgO with metallic ferromagnets such as Fe, CoFe, and CoFeB can exhibit a large perpendicular magnetic anisotropy which is furthermore sensitive to voltages applied across the dielectric layer. This effect has been attributed to spin-dependent charge screening, hybridization of atomic orbitals at the interface, and to the electric field induced modulation of the relative occupancy of atomic orbitals at the interface. In many embodiments, MEJs can exploit this phenomenon to achieve two distinct states. For example, MEJs can employ one of two mechanisms to do so.

First, in several embodiments of the invention, MEJs can be configured such that the application of a potential difference across the MEJ functions to reduce the coercivity of the FM free layer, such that it can be subject to magnetization in a desired magnetic direction. In certain embodiments, these directions may include being either substantially parallel with or antiparallel with the magnetization direction of the fixed layer. Second, in additional embodiments of the invention, MEJ operation can rely on precessional switching (or resonant switching), whereby by precisely subjecting the MEJ to voltage pulses of precise duration, the direction of magnetization of the FM free layer can be made to switch.

In a number of embodiments, MEJ operation is based on reducing the coercivity of the FM free layer such that it can adopt a desired magnetization direction. With a reduced coercivity, the FM free layer can adopt a magnetization direction in any suitable way. In multiple embodiments, the magnetization can result from an externally applied magnetic field, the magnetic field of the FM fixed layer, and/or the application of a spin-transfer torque (STT) current. In additional embodiments, the magnetization can further result from the magnetic field of a FM semi-fixed layer, the application of a current in an adjacent metal line inducing a spin-orbit torque (SOT), and/or any combination of these mechanisms. Indeed, such magnetization may occur from any suitable method of magnetizing the FM free layer with a reduced coercivity.

By way of example and not limitation, suitable ranges for the externally applied magnetic field are in the range of 0 to 100 Oe. However, in cases involving voltage induced precessional switching, to achieve a 1 nanosecond switching speed, the externally applied magnetic field should be approximately 200 Oe. The magnitude of the electric field applied across the device to reduce its coercivity or bring about resonant switching can be approximately in the range of 0.1-2.0 V/nm, with lower electric fields required for materials combinations that exhibit a larger VCMA effect. The magnitude of the STT current used to assist the switching may be in the range of approximately 0.1-1.0 MA/cm².

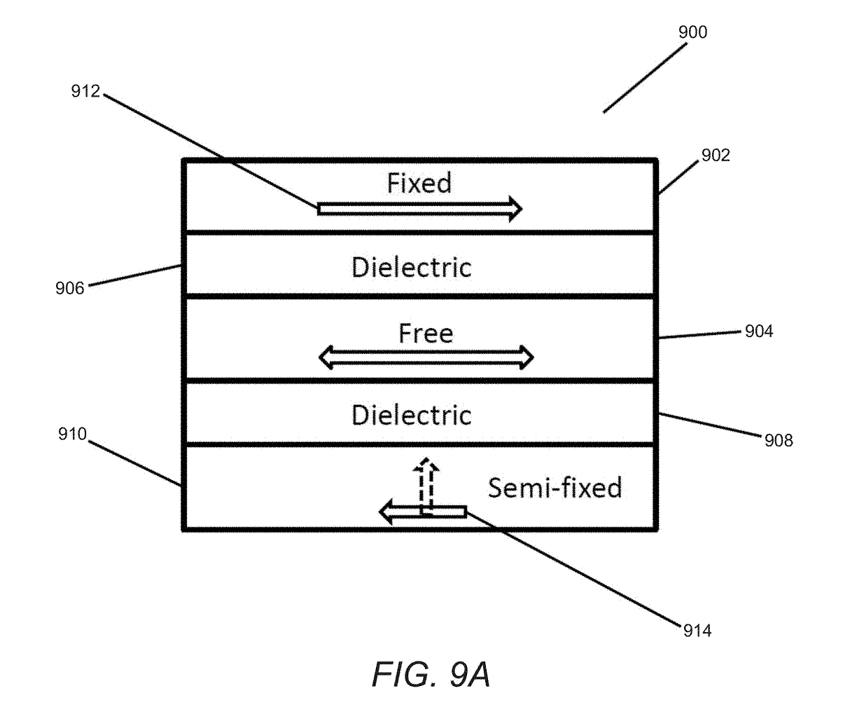

FIG. 8A conceptually illustrates how the application of a potential difference can reduce the coercivity of the free layer such that an externally applied magnetic field H can impose a magnetization switching on the free layer. In the illustration, in step 1, the FM free layer and the FM fixed layer have a magnetization direction that is substantially in plane, meaning that the FM free layer has a magnetization direction that is parallel with that of the FM fixed layer. Further, in step 1, the coercivity of the FM free layer is such that the FM free layer is not prone to having its magnetization direction reversed by the magnetic field H, which is in a direction antiparallel with the magnetization direction of the FM fixed layer. However, a voltage, V_{c} is then applied, which results in step 2, where the voltage V_{c} has magnified the perpendicular magnetization direction component of the free layer (out of its plane). Correspondingly, the coercivity of the FM free layer is reduced such that it is subject to magnetization by an in-plane magnetic field H. Accordingly, when the potential difference V_{c} is removed, VCMA effects are removed and the magnetic field H, which is substantially anti-parallel to the magnetization direction of the FM fixed layer, causes the FM free layer to adopt a direction of magnetization that is antiparallel with the magnetization direction of the FM fixed layer. Hence, as the MEJ now includes a FM fixed layer and a FM free layer that have magnetization directions that are antiparallel, it reads out a second information state (resistance value) different from the first. In general, it should be understood that in many embodiments where the magnetization directions of the free layer and the fixed layer are substantially in-plane, the application of a voltage enhances the perpendicular magnetic anisotropy such that the FM free layer can be caused to adopt an out-of-plane direction of magnetization. The magnetization direction can thereby be made to switch. In general, it can be seen that by controlling the potential difference and the direction of an applied external magnetic field, a MEJ switch can be achieved.

It should of course be understood that the direction of the FM fixed layer's magnetization direction need not be in-plane—it can be in any suitable direction. For instance, in certain embodiments, the magnetization can be substantially out of plane. Additionally, in many embodiments, the FM free layer can include both in-plane and out-of-plane magnetic anisotropy directional components. FIG. 8B depicts a corresponding case relative to FIG. 6 wherein the FM fixed and FM free layers have magnetization directions that are perpendicular to the layers of the MEJ (out-of-plane). It is of course important, that a FM, magnetically anisotropic free layer be able to adopt a magnetization direction that is either substantially parallel with an FM fixed layer, or substantially antiparallel with an FM fixed layer. In other words, when unburdened by a potential difference, the FM free layer can adopt a direction of magnetization that is either substantially parallel with or antiparallel with the direction of the FM fixed layer's magnetization to the extent that a distinct measurable difference in the resistance of the MEJ can be measured as two discrete information states.

Although specific conceptual illustrations are described regarding MEJ operation with respect to FIGS. 8A-B, any of a number of operation methods for MEJ systems can be utilized as appropriate to the requirements of specific applications in accordance with various embodiments of the invention. A discussion about utilizing semi-fixed layers in MEJs is covered in the following section.

### Utilizing Semi-Fixed Layers in Magneto-Electric Junctions

In a number of embodiments, MEJs can also include a semi-fixed layer that can have a magnetic anisotropy that is altered by the application of a potential difference. In many embodiments, the characteristic magnetic anisotropy of the semi-fixed layer is a function of the applied voltage. For example, the direction of the magnetization of the semi-fixed layer can be oriented in the plane of the layer in the absence of a potential difference across the MEJ. However, when a potential difference is applied in several embodiments of the invention, the magnetic anisotropy is altered such that the magnetization may include a strengthened out-of-plane component. Moreover, in several embodiments the magnetic anisotropy of the semi-fixed layer may be modified by an applied voltage. Furthermore, the amount of modification of the semi-fixed layer in the presence of the applied voltage may also be less than free layer magnetic anisotropy is modified as a function of the same applied voltage. In additional embodiments, the incorporation of a semi-fixed layer can facilitate a more nuanced operation of the MEJ (to be discussed below in the section entitled “MEJ Operating Principles”).

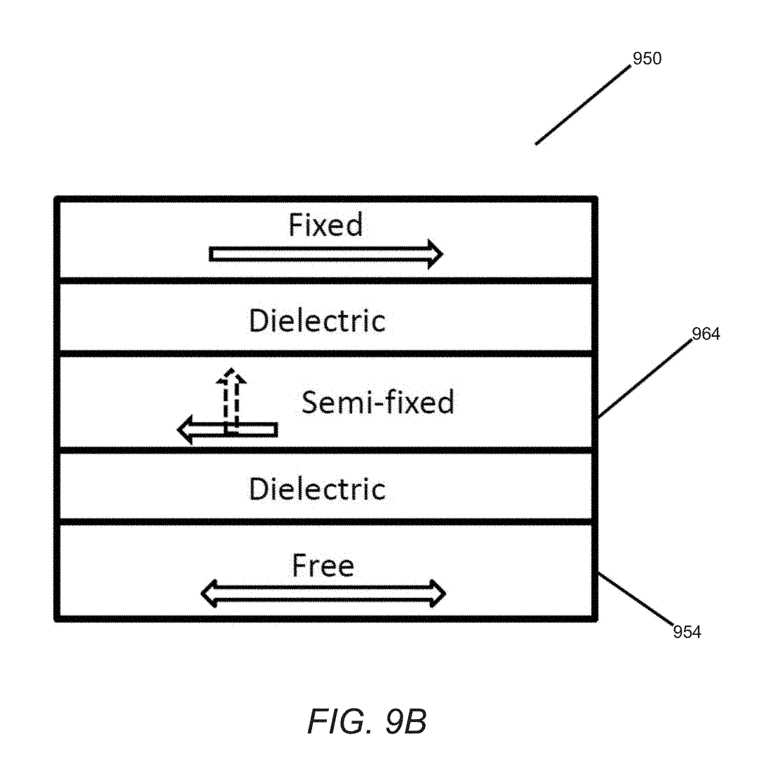

FIG. 9A conceptually illustrates a MEJ that includes a semi-fixed layer. In particular, the configuration of the MEJ 900 is similar to that depicted in FIG. 5, insofar as it includes a FM fixed layer 902 and a FM free layer 904 separated by a dielectric layer 906. However, in several embodiments, the MEJ 900 further includes a second dielectric layer 908 adjoined to the FM free layer 904 such that the FM free layer is adjoined to two dielectric layers, 906 and 908 respectively, on opposing sides. Further, in many embodiments, a semi-fixed layer 910 is adjoined to the dielectric layer. Typically, in many embodiments, the direction of magnetization of the semi-fixed layer 914 is antiparallel with that of the FM fixed layer 912. As mentioned above, the direction of magnetization of the semi-fixed layer can be manipulated based on the application of a voltage in accordance with a number of embodiments of the invention. In this illustration for example, it is depicted that the application of a potential difference adjusts the magnetic anisotropy of the semi-fixed layer such that the strength of the magnetization along a direction orthogonal to the initial direction of magnetization (in this case, out of the plane of the layer) is developed. It should of course be noted that the application of a potential difference could augment the magnetic anisotropy in any number of ways; for instance, in certain embodiments of MEJs, the application of a potential difference can reduce the strength of the magnetization in a direction orthogonal to the initial direction of magnetization. Note also that in the illustration, the directions of magnetization are all depicted to be in-plane where there is no potential difference. However, it should be understood that the direction of the magnetization can be in any suitable direction.

A particular configuration of a MEJ that includes a semi-fixed layer is depicted in FIG. 9A, however it should be understood that a semi-fixed layer can be incorporated within a MEJ in any number of configurations. For example, FIG. 9B conceptually illustrates a MEJ that includes a semi-fixed layer that is in a different configuration than that seen in 9A. In several embodiments, the positioning of the semi-fixed layer 964 and the free layer 954 is inverted of the MEJ 950. In certain situations, such a configuration may be more desirable.

Although specific conceptual illustrations are described above for utilizing semi-fixed layers in a MEJ with reference to FIGS. 9A-B, any of a number of semi-fixed layers in MEJ systems can be utilized as appropriate to the requirements of specific applications in accordance with various embodiments of the invention. A discussion on utilizing metallic lines in of the operation of a MEJ are discussed in the following section.

### Utilizing Metallic Lines in MEJs

Note of course that the application of an externally applied magnetic field is not the only way for the MEJ to take advantage of reduced coercivity upon application of a potential difference. In many embodiments, the magnetization of the FM fixed layer can be used to impose a magnetization direction on the free layer when the free layer has a reduced coercivity. Moreover, in several embodiments a MEJ can be configured to receive a spin-transfer torque (STT) current when application of a voltage causes a reduction in the coercivity of the FM free layer. Generally, certain embodiments include STT current as a spin-polarized current that can be used to facilitate the change of magnetization direction on a ferromagnetic layer. In a number of embodiments, this current can be passed directly through the MEJ device, such as due to leakage when a voltage is applied, or it can be created by other means. In several embodiments, these means can include spin-orbit-torques (e.g., Rashba or Spin-Hall Effects) or when a current is passed along a metal line placed adjacent to the FM free layer. Accordingly, a spin orbit torque current can then help cause the FM free layer to adopt a particular magnetization direction, where the direction of the spin orbit torque may determine the direction of magnetization. This configuration is advantageous over conventional STT-RAM configurations since the reduced coercivity of the FM free layer reduces the amount of current required to cause the FM free layer to adopt a particular magnetization direction, thereby making the device more energy efficient.

Additionally, in many embodiments, a MEJ cell can further take advantage of thermally assisted switching (TAS) principles. Generally, in numerous embodiments, in accordance with TAS principles, heating up the MEJ during a writing process may reduce the magnetic field required to induce switching. Thus, where STT is employed in accordance with several embodiments of the invention, even less current may be required to help impose a magnetization direction change on a free layer, particularly where VCMA principles have been utilized to reduce its coercivity.

Moreover, in numerous embodiments, the switching of MEJs to achieve two information states can also be achieved using voltage pulses. In particular, when voltage pulses are imposed on the MEJ for a time period that is one-half of the precession of the magnetization of the free layer, then the magnetization may invert its direction. Using this technique in certain embodiments of the invention, ultrafast switching times, e.g. below 1 ns, can be realized. Moreover, in additional embodiments using voltage pulses as opposed to a current makes this technique more energy efficient as compared to precessional switching induced by STT currents, as is often used in STT-RAM. However, this technique may be subject to the application of a precise pulse that is half the length of the precessional period of the magnetization layer. For instance, it has been observed that pulse durations in the range of 0.5 to 3 nanoseconds can reverse the magnetization direction. Additionally, the voltage pulse must be of suitable amplitude to cause the desired effect, e.g. reverse the direction of magnetization.

Based on this background, it can be seen that MEJs in accordance with embodiments of the invention can confer numerous advantages relative to conventional MTJs. For example, many embodiments can be controlled using voltages of a single polarity—indeed, the '739 patent, incorporated by reference above, discusses using diodes, in lieu of transistors, as access devices to the MEJ, and this configuration is enabled because MEJs can be controlled using voltage sources of a single polarity. In various embodiments, the charge current, spin current, and spin-polarization are all orthogonal to each other.

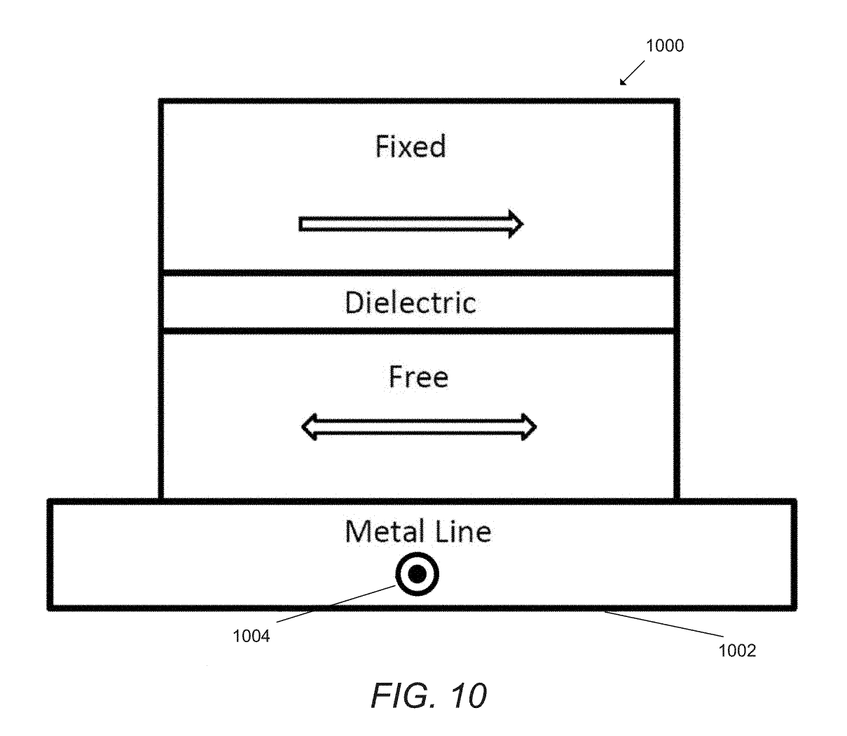

FIG. 10 conceptually illustrates using a metal line disposed adjacent to an FM free layer to generate spin-orbit torques that can impose a magnetization direction change on the FM free layer in accordance with several embodiments of the invention. In particular, the MEJ 1000 may be similar to that seen in FIG. 5, except that it further includes a metal line 1002, whereby a current 1004 can flow to induce spin-orbit torques, thereby helping to impose a magnetization direction change on the ferromagnetic free layer.

Although specific conceptual embodiments are described above regarding utilizing a metal line with MEJs with respect to FIG. 10, any of a number of methods to utilize a metal line adjacent to a MEJ system can be utilized as appropriate to the requirements of specific applications in accordance with various embodiments of the invention. A discussion about utilizing a plurality of MEJs in a configuration is covered in the following section.

Although the present invention has been described in certain specific aspects, many additional modifications and variations would be apparent to those skilled in the art. It is therefore to be understood that the present invention may be practiced otherwise than specifically described, including various changes in the implementation, without departing from the scope and spirit of the present invention. Additionally, the figures and methods described herein can also be better understood through the attached documentation the disclosure of which is hereby incorporated by reference in its entirety. Thus, embodiments of the present invention should be considered in all respects as illustrative and not restrictive.

What is claimed is:

1. A magnetoelectric random access memory circuit, comprising,
a plurality of voltage controlled magnetic tunnel junction bits wherein each magnetoelectric junction comprises:
at least one free magnetic layer;
one fixed magnetic layer; and
one dielectric interposed between the two magnetic layers;
wherein application of a voltage with a given polarity to the magnetoelectric junction reduces the perpendicular magnetic anisotropy and the magnetic coercivity of the free layer through the voltage controlled magnetic anisotropy (VCMA) effect;
wherein application of a voltage with opposite polarity increases the perpendicular magnetic anisotropy and magnetic coercivity of the free layer through the VCMA effect;
wherein each magnetoelectric junction is connected to the drain of an MOS transistor, the combination comprising a MeRAM cell;
wherein each MeRAM cell comprises three terminals, each connected respectively to a bit line, a source line, and at least one word line, in an array;
a pulse generator and a write MOS transistor connected to the bit line and the source line;
a sense amplifier and a sense MOS transistor connected to the source line and the bit line; and
a current source circuit connected to the source line and the reference line.

2. The magnetoelectric random access memory circuit of claim 1, wherein the magnetoelectric junction bit free layer comprises a combination of Co, Fe and B.

3. The magnetoelectric random access memory circuit of claim 1, wherein the magnetoelectric junction bit dielectric barrier comprises MgO.

4. The magnetoelectric random access memory circuit of claim 2, wherein the magnetoelectric junction bit free layer is placed adjacent to a metal layer, comprising one or a combination of the elements Ta, Ru, Mn, Pt, Mo, Ir, Hf, W, and Bi.

5. The magnetoelectric random access memory circuit of claim 1, wherein the free layer magnetization changes direction in response to a voltage pulse across the magnetoelectric junction bit, which is timed to approximately half the ferromagnetic resonance period of the free layer.

6. The magnetoelectric random access memory circuit of claim 5, wherein the free layer magnetization has two stable states which are perpendicular to plane in the absence of voltage.

7. The magnetoelectric random access memory circuit of claim 5, wherein the free layer magnetization has two stable states in plane in the absence of voltage.

8. The magnetoelectric random access memory circuit of claim 5, wherein the magnetoelectric junction bit has a circular shape.

9. The magnetoelectric random access memory circuit of claim 5, wherein the magnetoelectric junction bit has an elliptical shape.

10. The magnetoelectric random access memory circuit of claim 1, wherein the pulse generator involves a bit line driver.

11. The magnetoelectric random access memory circuit of claim 1, where the source of a MOS transistor of each MeRAM cell is connected to the source line.

12. The magnetoelectric random access memory circuit of claim 1, wherein at least one output of the current source circuit is connected to the source line and supplies a constant current during the read operation.

13. The magnetoelectric random access memory circuit of claim 1, wherein a second output of the current source circuit is connected to the reference line and supplies a constant current during the read operation.

14. The magnetoelectric random access memory circuit of claim 1, wherein at least one input of the sense amplifier is connected to the source line.

15. The magnetoelectric random access memory circuit of claim 1, wherein a second input of the sense amplifier is connected to the reference line.

16. The magnetoelectric random access memory circuit of claim 1, wherein the drain of a MOS transistor is connected to the reference line.

17. The magnetoelectric random access memory circuit of claim 16, wherein the source of a MOS transistor is connected to a reference resistor.

18. The magnetoelectric random access memory circuit of claim 1, wherein the drain of the sense MOS transistor is connected to the bit line.

19. The magnetoelectric random access memory circuit of claim 1, wherein the drain of the write MOS transistor is connected to the source line.
